(19) United States
(12) Patent Application Publication
(10) Pub. No.: US 2002/0090752 A1
(43) Pub. Date: Jul. 11, 2002

(54) Semiconductor device, and apparatus and method for die bonding the same

(75) Inventor: Makoto Nakanishi, Tokyo (JP)

Correspondence Address: McDermontt, Will & Emery, 600 13th street, N. W., Washington, DC, 20005-3096, US

(73) Assignee: Mitsubishi Denki Kabushiki Kaisha

(21) Appl. No.: 09/908,894

(22) Filed: Jul. 20, 2001

(30) Foreign Application Priority Data
Jan. 5, 2001 (JP) 2001-000407

(51) Int. Cl. H01L 21/44; H01L 21/48

(52) U.S. Cl. 438/107; 438/118; 257/680

(57) ABSTRACT

A low-cost semiconductor device, and an apparatus and a method for die bonding such a semiconductor device using no or extremely small quantities of bonding materials containing Pb, as well as other bonding materials, from the consideration to the environment. In a semiconductor device including a die 1 and a die pad 2 fixed to each other at facing surfaces 1a and 2a, a hollow portion 3 is formed in at least a part of the facing surfaces 1a and 2a, and the die 1 and the die pad 2 are fixed so that the internal pressure of the hollow portion 3 is kept lower than the external pressure.

### BACKGROUND OF THE INVENTION

1. Field of the Invention

The present invention relates to a semiconductor device manufactured through a die bonding assembly process in which a die is fixed to a die pad, and an apparatus and a method for die bonding such a semiconductor device.

2. Description of Related Art

FIG. 8 is a sectional view showing a semiconductor device after a conventional die bonding assembly process. In FIG. 8, the reference numeral 1 indicates a die (silicon chip), 2 indicates a die pad corresponding to the fixing section of a die on a frame, and 5 indicates a Pb-Sn-based solder used as a bonding material.

The die 1 is fixed to the die pad 2 by having the Pb—Sn—based solder 5 intervene between the facing surface 1a of the die 1 and the facing surface 2a of the die pad 2.

Also in Japanese Patent Laid-Open No. 5-102208, although not shown in the drawings, a technique for performing a die bonding assembly process in vacuum in order to prevent the plated surface from oxidation when plating is used for bonding material used between the facing surfaces of the die and the die pad.

In the above-described prior art, the Pb—Sn—based solder used for bonding the die and the die pad contains Pb. However, when the environment of assembling factories or markets of semiconductor device is considered, it is not preferred from the long-term point of view to continue the use of Pb—Sn—based solder containing Pb. Particularly in recent years, the acquisition of the approval of the international standards, ISO, is essential for corporations to export their products smoothly, and the development of semiconductor devices or die bonding methods without using Pb—Sn—based solder is of urgent necessity.

At present, bonding materials that have been used practically other than Pb—Sn—based solder include thermosetting resins and plating. Although no problems as described above arise when using these bonding materials because Pb is not contained, other restrictions will arise in that the material costs are not so low, and the process control is not so easy as in the use of Pb—Sn—based solder.

### SUMMARY OF THE INVENTION

The present invention has been devised to solve the above-described problems, and a first object of the present invention is to provide a low-cost semiconductor device, and an apparatus and a method for die bonding such a semiconductor device using no or extremely small quantities of bonding materials containing Pb, as well as other bonding materials, from the consideration to the environment.

A second object of the present invention is to provide a semiconductor device of stable quality, and an apparatus and a method for die bonding such a semiconductor device using no bonding materials, by steadily preventing the deformation and detachment of the die in the semiconductor device without using bonding materials according to the method of the present invention.

According to a first aspect of the present invention, there is provided a semiconductor device comprising a die and a die pad fixed to each other at facing surfaces thereof, wherein, a hollow portion is formed in at least a part of the facing surfaces, and the die and the die pad are fixed by keeping the internal pressure of the hollow portion lower than the external pressure.

According to a second aspect of the present invention, there is provided a die attach machine for a semiconductor device comprising, a housing that accommodates at least a wafer holding section for holding a wafer having a die, a frame holding section for holding a frame having a die pad, a mounting section for mounting the die on the die pad, a die supplying section for supplying the die on the wafer to the loading section, and a frame supplying section for supplying the frame to the loading section; and a pressure controlling section for controlling the internal pressure of the housing, wherein a hollow portion is provided on at least a part of the facing surfaces of the die and die pad.

According to a third aspect of the present invention, there is provided a method for die bonding a semiconductor device comprising the steps of: mounting a die on a die pad provided with a hollow portion on at least a part of the surface facing to the die after reducing the pressure in a space where the mounting is performed; and returning the reduced pressure of the space to the external pressure after the pressure-reducing step.

The above and other objects, effects, features and advantages of the present invention will become more apparent from the following description of the embodiments thereof taken in conjunction with the accompanying drawings.

### BRIEF DESCRIPTION OF THE DRAWINGS

FIG. 1 is a schematic perspective view showing a semiconductor device of First Embodiment of the present invention during die bonding assembly.

FIG. 2 is a schematic perspective view showing a semiconductor device of Second Embodiment of the present invention during die bonding assembly.

FIG. 3 is a schematic perspective view showing a semiconductor device of Third Embodiment of the present invention during die bonding assembly.

FIG. 4 is a schematic perspective view showing a semiconductor device of Fourth Embodiment of the present invention during die bonding assembly.

FIG. 5 is a schematic perspective view showing a semiconductor device of Fifth Embodiment of the present invention during die bonding assembly.

FIG. 6 is a schematic diagram showing the die attach machine for semiconductor devices according to Sixth Embodiment.

FIG. 7 is a schematic diagram showing the die attach machine for semiconductor devices according to Seventh Embodiment.

FIG. 8 is a sectional view showing a semiconductor device after a conventional die bonding assembly process.

### DETAILED DESCRIPTION OF THE PREFERRED EMBODIMENTS

Embodiments of the present invention will be described below with reference to the accompanying drawings. It is noted that the same reference symbols in the drawings denote the same or corresponding components.

First Embodiment

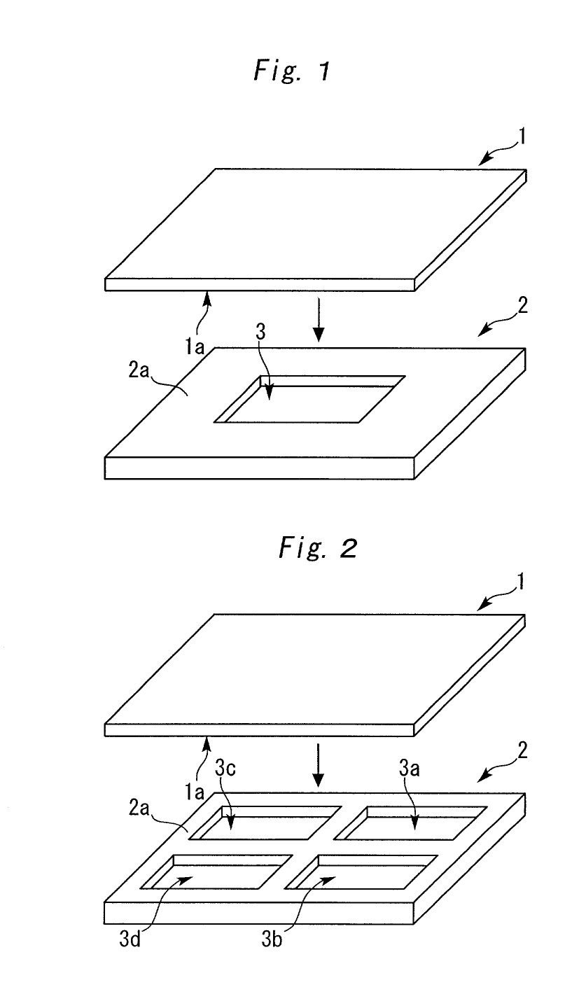

First Embodiment of the present invention will be described in detail below referring to the drawings. FIG. 1 is a schematic perspective view showing a semiconductor device of First Embodiment of the present invention during die bonding assembly. In FIG. 1, the reference numeral 1 indicates a die, and 2 indicates a die pad. As will be described later, the die bonding process is completed by moving the die 1 in the direction of the arrow in FIG. 1, and fixing the die 1 on the predetermined location of the die pad 2, so that the facing surface 1a of the die 1 is put upon the facing surface 2a of the die pad 2.

Here, the facing surface 1a of the die 1 and the facing surface 2a of the die pad 2 are formed of flat materials, or secondarily processed, so that both surfaces become flat. Also in the die pad 2, a recessed hollow portion 3 is formed at the side of the surface 2a facing to the die 1. That is, the length in the height direction (depth) of the hollow portion 3 is made shorter than the length in the height direction (thickness) of the die pad 2, and the hollow portion 3 has the form of a blind hole (non-through hole).

The opening area of the hollow portion 3 is made smaller than the area of the facing surface 1a of the die 1, and after die bonding, the opening of the hollow portion 3 is fixed so as to be positioned at almost the center of the facing surface 1a of the die 1. That is, the completed semiconductor device has the hollow portion 3 that is a space sealed from the exterior after die bonding. The internal pressure of the sealed hollow portion 3 is made lower than the external pressure (atmospheric pressure). Thereby, the die 1 and the die pad 2 are sucked and fixed to each other by pressure difference between interior and exterior. Therefore, in order to obtain stronger suction force, it is preferable that the internal pressure of the hollow portion 3 is nearly vacuum.

The specific method for lowering the internal pressure of the hollow portion 3 will be described in detail later in the embodiment related to a die attach machine, and will be described briefly here. First, prior to the die bonding assembly process for the die 1 and die pad 2, the pressure in the die attach machine containing a mounting section for mounting the die 1 on the die pad 2 equivalent to the external pressure is reduced to a lower pressure. Next, under the lower pressure, the die 1 is mounted on the die pad 2. Finally, the pressure in the die attach machine is returned to the pressure equivalent to the external pressure.

Here, as described above, since the facing surfaces 1a and 2a of the die 1 and the die pad 2, respectively, are flat, the hollow portion 3 formed after the die bonding assembly process is maintained airtight. Thereby, the internal pressure of the hollow portion 3 after the die bonding assembly process is maintained lower than the external pressure. This internal-external pressure difference causes the die 1 and the die pad 2 to suck each other, and the die 1 and the die pad 2 are fixed.

According to the semiconductor device constituted as in First Embodiment, as described above, since no Pb—Sn—based solder is used as the bonding material, a clean environment is provided in assembling factories and the like. Furthermore, since no other bonding materials are used for die bonding the die 1 and the die pad 2, the material costs per completed product are low, and tools for using bonding materials and the control thereof become unnecessary. Also, defective products due to the detachment of dies 1 caused by insufficient application of the bonding materials are not produced, resulting in the improvement of product yield.

Second Embodiment

Second Embodiment of the present invention will be described in detail below referring to the drawings. FIG. 2 is a schematic perspective view showing a semiconductor device of Second Embodiment of the present invention during die bonding assembly. The semiconductor device shown in FIG. 2 differs from the semiconductor device of the above-described First Embodiment, and four recessed hollow portions 3a, 3b, 3c, and 3d are formed on the facing surface 2a of the die pad 2. That is, all of the four hollow portions 3a, 3b, 3c, and 3d have a blind-hole shape.

The total area of the opening regions of the four hollow portions 3a, 3b, 3c, and 3d are made smaller than the area of the facing surface 1a of the die 1, and the die 1 is fixed to the die pad 2, so that the center of the opening regions of the four hollow portions 3a, 3b, 3c, and 3d positions on almost the center of the facing surface 1a of the die 1. That is, after die bonding assembly, the completed semiconductor device has four hollow portions 3a, 3b, 3c, and 3d, which are spaces sealed from the exterior. The internal pressures of all of these four sealed hollow portions 3a, 3b, 3c, and 3d are made lower than the external pressure. This internal-external pressure difference causes the die 1 and the die pad 2 to be fixed to each other.

The specific method for lowering the internal pressure of the hollow portions 3a, 3b, 3c, and 3d is the same as in the above-described First Embodiment.

According to the semiconductor device constituted as in Second Embodiment, as in the above-described First Embodiment, a clean environment is provided in assembling factories and the like. Furthermore, the material costs per completed product are low, product yield is improved, and tools for using bonding materials and the control thereof become unnecessary.

In Second Embodiment, although four hollow portions 3a, 3b, 3c, and 3d are formed, and the shape of the openings is rectangular, the number and the shape of hollow portions 3 are not limited to the above, and the same effects can be obtained from other structures.

Third Embodiment

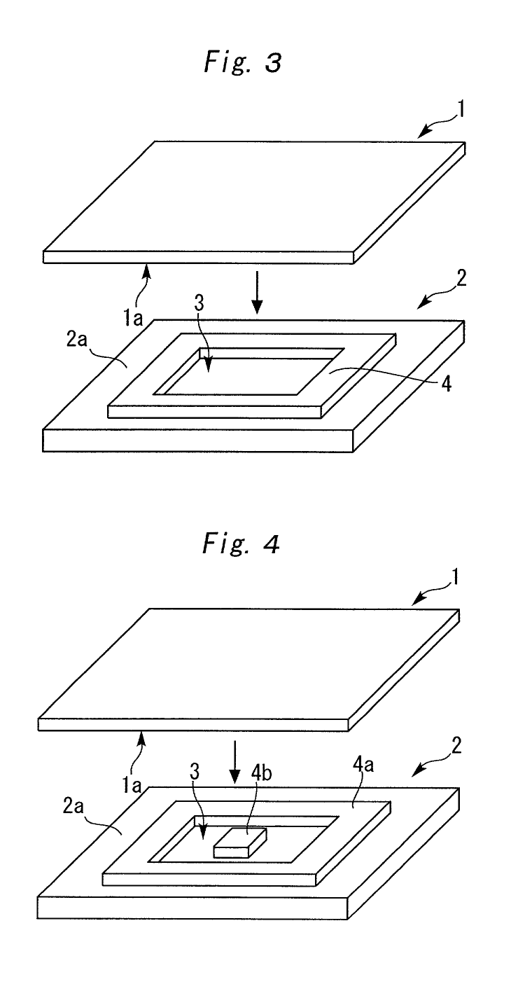

Third Embodiment of the present invention will be described in detail below referring to the drawings. FIG. 3 is a schematic perspective view showing a semiconductor device of Third Embodiment of the present invention during die bonding assembly. The semiconductor device shown in FIG. 3 differs from the semiconductor device of the above-described First Embodiment having the recessed hollow portion 3 on the facing surface 2a, in that an annular rim 4 protruded from the facing surface 2a of the die pad 2 is provided.

In FIG. 3, the reference numeral 1 indicates a die, and 2 indicates a die pad. On the facing surface 2a of the die pad 2 is formed the above-described rim 4 integrally with the die pad 2. The opening area of the rim 4 is made smaller than the area of the facing surface 1a of the die 1. The die 1 is moved in the direction of the arrow in FIG. 3 so that the facing surface 1a of the die 1 faces to the facing surface of the rim 4, and is fixed so that the center of the facing surface 1a of the die 1 is positioned at almost the center of the opening of the rim 4. Thereby, a hollow portion 3 is formed after die bonding.

Both the facing surface 1a of the die 1 and the facing surface of the rim 4 are made flat, whereby the hollow portion 3 formed after die bonding is maintained airtight.

In Third Embodiment, as in the above-described First Embodiment, the internal pressure of the hollow portion 3 formed after die bonding is made lower than the external pressure. This internal-external pressure difference causes the die 1 and the die pad 2 to be fixed to each other. The specific method for lowering the internal pressure of the hollow portion 3 is the same as in the above-described First Embodiment.

According to the semiconductor device constituted as in Third Embodiment, as in the above-described First Embodiment, a clean environment is provided in assembling factories and the like. Furthermore, the material costs per completed product are low, product yield is improved, and tools for using bonding materials and the control thereof become unnecessary.

According to the constitution of Third Embodiment, although the hollow portion 3 is formed only by providing the rim 4 on the die pad 2, the present invention is not limited thereto, but can be formed, for example, by combining the above-described First Embodiment and Third Embodiment. That is, the same effect can be obtained from the structure that has both a recessed portion and a protruded rim 4 on the facing surface 2a of the die pad 2.

Fourth Embodiment

Fourth Embodiment of the present invention will be described in detail below referring to the drawings. FIG. 4 is a schematic perspective view showing a semiconductor device of Fourth Embodiment of the present invention during die bonding assembly. The semiconductor device shown in FIG. 4 is the same as the semiconductor device of the above-described Third Embodiment in that a protruded rim 4a is formed on the facing surface 2a of the die pad 2, but differs from the semiconductor device of the above-described Third Embodiment in that a protruded portion 4b protruding in the same direction as the protruding direction of the rim 4a is formed on the center of the rim 4a.

In FIG. 4, the height of the protruded portion 4b formed on the facing surface 2a of the die pad 2 is made substantially the same as the height of the rim 4a so as to contact the facing surface 1a of the die 1. In the same manner as in the above-described Third Embodiment, a hollow portion 3 is formed after die bonding.

Here, also in Fourth Embodiment as in the above-described Third Embodiment, the internal pressure of the hollow portion 3 formed after die bonding is made lower than the external pressure. Thereby, the internal-external pressure difference causes the die 1 and the die pad 2 to be fixed to each other. The specific method for lowering the internal pressure of the hollow portion 3 is the same as in the above-described Third Embodiment.

According to the semiconductor device constituted as in Fourth Embodiment, the same effects can be obtained as in the above Third Embodiment. In addition, in Fourth Embodiment, when the die 1 is sucked to the die pad 2 by interior-exterior pressure difference, the protruded portion 4b acts as the support to control the deformation of the die 1 within the required limit even if the rigidity of the die 1 is insufficient.

Therefore, as far as the constituting surface of the protruded portion 4b is concerned, the flatness of the facing surface of the protruded portion 4b is not so required. Regarding the facing surface 1a of the die 1 and the facing surface of the rim 4a, although surface flatness is required to maintain the air tightness of the hollow portion 3, the surface flatness of the facing surface of the protruded portion 4b is not required because the role of the facing surface of the protruded portion 4b is to support the die 1, and the function is different.

Referring to FIG. 2, in the above-described Second Embodiment, since the facing surface 2a of the die pad 2 is formed to be a cross-shape in the center, this portion plays the role of the support of the die 1 in the same manner as in Fourth Embodiment, but the flatness of the surface is required from the structure thereof.

Also, although the shape of the protruded portion 4b is rectangular in the constitution of Fourth Embodiment, the same effect as in Fourth Embodiment can be obtained even if the shape is not limited to the rectangular shape.

Fifth Embodiment

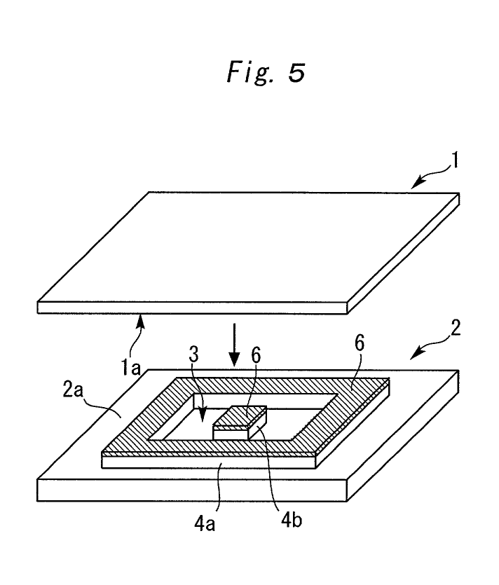

Fifth Embodiment of the present invention will be described below in detail referring to the drawings. FIG. 5 is a schematic perspective view showing a semiconductor device of Fifth Embodiment of the present invention during die bonding assembly. The semiconductor device shown in FIG. 5 is the same as the semiconductor device of the above-described Fourth Embodiment in that a protruded rim 4a and a protruded portion 4b are formed on the facing surface 2a of the die pad 2, but differs from the semiconductor device of the above-described Fourth Embodiment only in that the facing surfaces of the protruded rim 4a and the protruded portion 4b are provided with a sealing material 6.

In FIG. 5, the height of the rim 4a and the protruded portion 4b formed on the facing surface 2a of the die pad 2 is designed to be substantially the same, and a sealing material 6 is applied onto the surfaces thereof. Here, the sealing material 6 itself is a highly airtight material, and produces no gap at the contacting portions with the die 1, the die pad 2, the rim 4, and the like. The sealing materials 6 that satisfy these requirements include, for example, glass, which is a suitable material because it is inexpensive, and environment friendly.

As in the above-described Fourth Embodiment, a hollow portion 3 is formed after die bonding.

Here, also in Fifth Embodiment as in the above-described Fourth Embodiment, the internal pressure of the hollow portion 3 formed after die bonding is made lower than the external pressure. Thereby, the internal-external pressure difference causes the die 1 and the die pad 2 to be fixed to each other. The specific method for lowering the internal pressure of the hollow portion 3 is the same as in the above-described Fourth Embodiment other than the step for forming the sealing material 6.

According to the semiconductor device constituted as in Fifth Embodiment, the same effects can be obtained as in the above Fourth Embodiment. In addition, in Fifth Embodiment, the hollow portion 3 is surely airtight because of the effect of the sealing material 6, even if the surface flatness of the facing surface 1a of the die 1 and the facing surface of the rim 4a is not sufficient.

In Fifth Embodiment, although the sealing material 6 is applied also onto the protruded portion 4b on the die pad 2, the same effect as in Fifth Embodiment can be obtained from the structure in which the sealing material 6 is applied only onto the rim 4a but not onto the protruded portion 4b.

Also, the application of the sealing material 6 is not limited to the structure of Fifth Embodiment, and the same effect as in Fifth Embodiment can be obtained from the application of the sealing material 6 on the facing surface 2a of the die pad 2a in the above-described First Embodiment and the like.

Sixth Embodiment

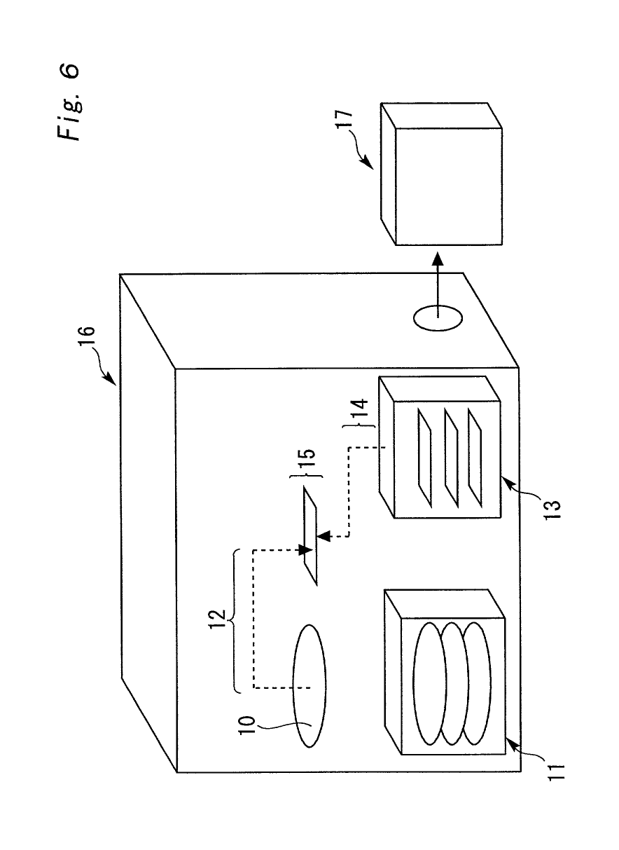

Sixth Embodiment of the present invention will be described below in detail referring to the drawings. FIG. 6 is a schematic diagram showing the die attach machine for semiconductor devices according to Sixth Embodiment. In FIG. 6, the reference numeral 10 indicates a wafer produced from an expanded silicon wafer material, 11 indicates a wafer holding section for holding a predetermined number of wafers 10, 12 indicates a die supplying section for supplying dies on the wafers to the mounting section 15, 13 indicates a frame holding section for holding a predetermined number of frames containing die pads, 14 indicates a frame supplying section for supplying frames in the frame holding section 13 to the mounting section 15, 15 is a mounting section for mounting dies on the predetermined position of the die pad in the supplied frame, 16 indicates a housing for accommodating a part of the die attach machine, and 17 indicates a pressure controlling section for reducing the pressure in the housing 16 and returning the reduced pressure to the external pressure.

Here, the housing 16 accommodates the least required sections for the die bonding assembly process. That is, the housing 16 accommodates wafer holding section 11, the die supplying section 12, the frame holding section 13, the frame supplying section 14, and the mounting section 15. The housing 16 is so constituted as to maintain the air-tightness of the interior.

The pressure controlling section 17 is directly connected to the housing 16, and can reduce the pressure in the housing 16 under the sealed state (including vacuum), and can return the reduced pressure to the external pressure. An example of the pressure controlling section 17 is a rotary pump having the pressure reducing function.

The semiconductor device manufactured using the die attach machine according to Sixth Embodiment is a semiconductor device of the structure having a hollow portion 3 in the die pad 2 shown in the above-described Embodiments 1 to 4.

In the die attach machine thus constituted, first the wafer holding section 11 that holds a predetermined number of wafers 10, and the frame holding section 13 that holds a corresponding number of frames are set in the housing 16 in the state where an insertion port (not shown) is open.

Next, the above-described insertion port is closed to make the housing 16 in a sealed state, and the gas in the housing 16 is evacuated out of the housing 16 by operating the pressure controlling section 17 to reduce the internal pressure of the housing 16. At this time, the internal pressure of the housing 16 is preferably close to vacuum.

In the housing 16, a frame is extracted from the frame holding section 13 by the frame supplying section 14, and the frame is transferred and supplied to the mounting section 15. On the other hand, a wafer 10 is transferred from the wafer holding section 11 to a predetermined position, and a die extracted from the wafer 10 is transferred and supplied to the mounting section 15 by the die supplying section 12.

In the mounting section 15, the die is mounted on the predetermined position of the die pad on the frame. By repeating these steps, the dies on corresponding wafers 10 are sequentially mounted on the die pads on all the frames loaded on the frame holding section 13. Then, the frames on which the dies are mounted are sequentially returned to the frame holding section 13, while the wafers 10 that have supplied the dies are sequentially returned to the wafer holding section 11.

After the completion of die mounting on the die pads, the pressure controlling section 17 is operated to return the internal pressure of the housing 16, which has been maintained under a reduced pressure, to the external pressure. Specifically, the air may be fed directly in the housing 16, or the air may be taken in by opening a hole that can be opened or closed and formed on a part of the external wall of the housing 16.

The frame holding section 13 loaded with the frames having the die pads on which the dies are fixed is transferred via the insertion port out of the housing 16, and the process is shifted to the next step.

Through the above-described process, since the semiconductor device after die bonding assembly has a hollow section, which is a space sealed from the exterior, the internal pressure of the hollow portion is made lower than the external pressure. Thereby, the internal-external pressure difference causes the die 1 and the die pad 2 to suck each other, and the die 1 and the die pad 2 are fixed.

As described above, according to the die attach machine for semiconductor devices constituted as in Sixth Embodiment and the die bonding method using such a die attach machine, since no Pb-Sn-based solder is used as the bonding material, a clean environment is provided in assembling factories and the like. Furthermore, since no other bonding materials are used for die bonding the die 1 and the die pad 2, the material costs per completed product are low, and tools for using bonding materials and the control thereof become unnecessary. On the other hand, although it is required to accommodate a part of the die attach machine related to the die bonding process in the housing 16, and the pressure controlling section 17 is used for reducing the internal pressure of the housing 16, the tools are relatively inexpensive and compact, and the control of the tools is easy, because the control of the tools are mainly pressure control, and complicated temperature control and the like are unnecessary.

In Sixth Embodiment, although the wafer holding section 11 on which a plurality of wafers 10 are loaded, and the frame holding section 13 on which a plurality of frames are loaded are accommodated in the housing 16, the same effect as in Sixth Embodiment can be obtained if one wafer 10 is loaded on the wafer holding section 11, and one frame is loaded on the frame holding section 13.

Also in the process for reducing the pressure in the housing 16 with the pressure controlling section 17 in Sixth Embodiment, the reduced pressure in the housing 16 is maintained until the completion of mounting all the dies on the die pads for wafers 10 loaded on the wafer holding section 11 and frames loaded on the frame holding section 13. However, apart from this, the same effect as in Sixth Embodiment can be obtained if the process to returning the reduced pressure to the external pressure is repeated for each step for loading a die on a die pad.

Seventh Embodiment

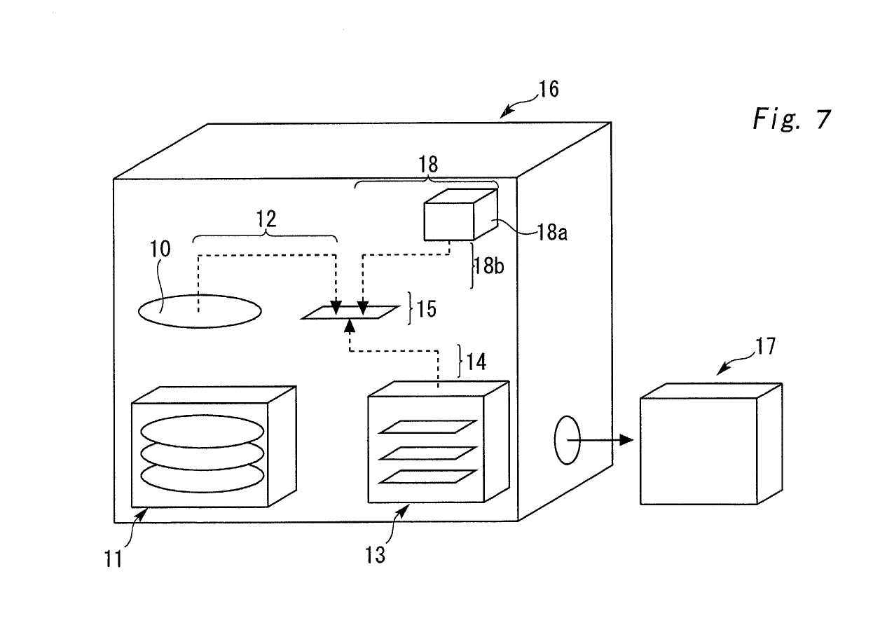

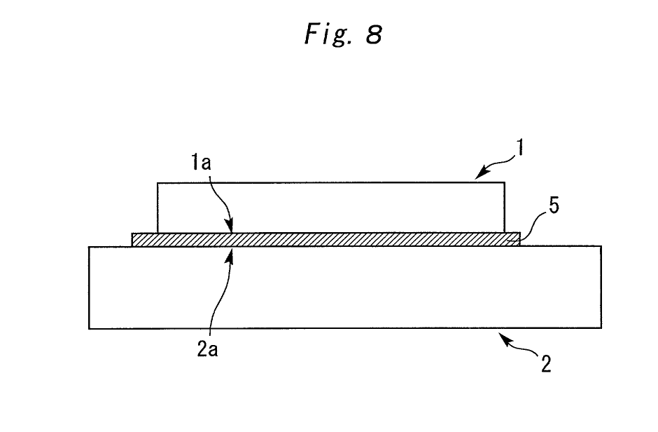

Seventh Embodiment of the present invention will be described below in detail referring to the drawings. FIG. 7 is a schematic diagram showing the die attach machine for semiconductor devices according to Seventh Embodiment. The die attach machine for semiconductor devices according to Seventh Embodiment shown in FIG. 7 differs from the apparatus of Sixth Embodiment only in that a sealing material supplying section 18 is provided in addition to the die attach machine of the above-described Sixth Embodiment.

In FIG. 7, the reference numeral 18 indicates a sealing material supplying section. The sealing material supplying section 18 is accommodated in the housing 16 together with the wafer holding section 11, the die supplying section 12, the frame holding section 13, the frame supplying section 14, and the mounting section 15. The sealing material supplying section 18 comprises mainly a sealing material holding section 18a for holding the sealing material, and a sealing material supplying section 18b for supplying the sealing material from the sealing material holding section 18a onto die pads.

The sealing material is used for manufacturing the semiconductor device shown in the above-described Fifth Embodiment, and specifically, for enhancing the air-tightness of the hollow portion formed thereafter by applying the sealing material onto the die pad of the frame supplied to the mounting section 15. Therefore, the sealing material itself is a highly airtight material, and produces no gap at the contacting portions with the die, the die pad, and the like. The sealing materials that satisfy these requirements include, for example, glass, which is a suitable material because it is inexpensive, and environment friendly.

An example of a die attach machine using glass as the sealing material, and a die bonding method using such an apparatus will be described referring to FIG. 7. In the die attach machine constituted as described above, first the wafer holding section 11 that holds a predetermined number of wafers 10, and the frame holding section 13 that holds a corresponding number of frames are set in the housing 16 as in the Sixth Embodiment. Next, after sealing the housing 16, the internal pressure of the housing is reduced.

In the housing 16, a frame is extracted from the frame holding section 13 by the frame supplying section 14, and the frame is transferred and supplied to the mounting section 15. On the other hand, a wafer 10 is transferred from the wafer holding section 11 to a predetermined position, and a die extracted from the wafer 10 is transferred and supplied to the mounting section 15 by the die supplying section 12.

In the above-described sealing material holding section 18a, on the other hand, liquefied glass at a high temperature is held as the sealing material. By the operation of the sealing material supplying section 18b, glass from the sealing material holding section 18a is applied on a part of the facing surface on the die pad of the frame transferred and supplied to the mounting section 15.

The mounting section 15 mounts a die on the predetermined position of the die pad on which glass has been applied. By repeating these steps, dies on the corresponding wafers 10 are sequentially mounted on the die pads on all the frames loaded in the frame holding section 13.

After the completion of mounting dies on the die pads, the internal pressure of the housing 16 held under a reduced pressure is returned to the external pressure as in the above-described Sixth Embodiment. On the other hand, the glass applied between the die and the die pad is solidified as it cools from a high temperature to a normal temperature.

Through the above-described process, since the semiconductor device after die bonding assembly has a hollow section, which is a space sealed from the exterior, the internal pressure of the hollow portion is made lower than the external pressure. Furthermore, since a sealing material is applied between the facing surfaces of the die and die pad, the die and die pad are sucked and fixed to each other due to internal-external pressure difference without depending on the flatness of the facing surfaces of the die and die pad.

As described above, according to the die attach machine for semiconductor devices constituted as in Seventh Embodiment and the die bonding method using such a die attach machine, a clean environment is provided in assembling factories and the like as in the above-described Sixth Embodiment. Furthermore, even though a sealing material is used, the range of applying the sealing material is limited to a part of the area on the die pad, and the material costs per completed product becomes low.

Although Seventh Embodiment comprises a step for applying a sealing material on the die pad prior to the step of mounting the die on the die pad, the desired air tightness can be maintained by comprising a step for applying a sealing material to the interface of the die and the die pad after the step of mounting the die on the die pad.

It is obvious that the present invention is not limited to the above-described embodiments, but each embodiment can be modified to other than suggested in each embodiment within the scope of the technical concept of the present invention. Also, the number, the position, or the shape of the above-described components are not limited to those in the above-described embodiments, but the optimal number, position and shape can be selected for executing the present invention. In each drawing, the same reference numerals are used for the same components.

Since the present invention is constituted as described above, no Pb-containing bonding materials are used for the consideration to the environment, and since no other bonding materials are used, an inexpensive semiconductor device without using bonding materials, and an apparatus and a method for die bonding can be provided.

Also, since a member for supporting the die is formed at the center of the hollow portion formed between the die and the die pad, the deformation of the die in the semiconductor device according to the present invention can be prevented, and a high-quality semiconductor device without using bonding materials, and an apparatus and a method for die bonding can be provided.

Since a sealing material is provided between the facing surfaces of the die and the die pad, the air-tightness of the hollow portion in the semiconductor device according the present invention can be enhanced regardless of the flatness of the facing surfaces of the die and the die pad, the detachment of the die can be prevented, and a high-quality semiconductor device without using bonding materials, and an apparatus and a method for die bonding can be provided.

In the semiconductor device, the hollow portion may be formed by providing a recessed portion in the facing surface of the die pad.

In the semiconductor device, the hollow portion may be formed by providing a protruded annular rim in the facing surface of the die pad.

In the semiconductor device, the hollow portion may be provided with a protruded portion that is brought into contact with the facing surface of the die.

In the semiconductor device, a sealing material may be provided on the facing surfaces of the die and die pad.

In the semiconductor device, the sealing material may be a glass material.

Here, the die attach machine for a semiconductor device, the housing may further accommodate a sealing-material supplying section for supplying a sealing material to the facing surfaces of the die and die pad.

In the die attach machine for a semiconductor device, the sealing material may be a glass material.

Here, the method for die bonding a semiconductor device, prior to mounting the die on the die pad, may further comprise the step of supplying a sealing-material to the facing surfaces of the die and die pad.

In the method for die bonding a semiconductor device, the sealing material may be a glass material.

The present invention has been described in detail with respect to various embodiments, and it will now be apparent from the foregoing to those skilled in the art that changes and modifications may be made without departing from the invention in its broader aspects, and it is the invention, therefore, in the appended claims to cover all such changes and modifications as fall within the true spirit of the invention.

The entire disclosure of Japanese Patent Application No. 2001-000407 filed on Jan. 5, 2001 including specification, claims, drawings and summary are incorporated herein by reference in its entirety.

What is claimed is:

1. A semiconductor device comprising a die and a die pad fixed to each other at facing surfaces thereof, wherein,
a hollow portion is formed in at least a part of said facing surfaces, and said die and said die pad are fixed by keeping the internal pressure of said hollow portion lower than the external pressure.

2. The semiconductor device according to claim 1, wherein said hollow portion is formed by providing a recessed portion in said facing surface of said die pad.

3. The semiconductor device according to claim 2, wherein said hollow portion is formed by providing a protruded annular rim in said facing surface of said die pad.

4. The semiconductor device according to claim 3, wherein said hollow portion is provided with a protruded portion that is brought into contact with the facing surface of said die.

5. The semiconductor device according to claim 4, wherein a sealing material is provided on the facing surfaces of said die and die pad.

6. The semiconductor device according to claim 5, wherein said sealing material is a glass material.

7. The semiconductor device according to claim 3, wherein a sealing material is provided on the facing surfaces of said die and die pad.

8. The semiconductor device according to claim 2, wherein said hollow portion is provided with a protruded portion that is brought into contact with the facing surface of said die.

9. The semiconductor device according to claim 8, wherein a sealing material is provided on the facing surfaces of said die and die pad.

10. The semiconductor device according to claim 2, wherein a sealing material is provided on the facing surfaces of said die and die pad.

11. The semiconductor device according to claim 1, wherein said hollow portion is provided with a protruded portion that is brought into contact with the facing surface of said die.

12. The semiconductor device according to claim 11, wherein a sealing material is provided on the facing surfaces of said die and die pad.

13. The semiconductor device according to claim 1, wherein a sealing material is provided on the facing surfaces of said die and die pad.

14. A die attach machine for a semiconductor device comprising,
a housing that accommodates at least a wafer holding section for holding a wafer having a die, a frame holding section for holding a frame having a die pad, a mounting section for mounting said die on said die pad, a die supplying section for supplying said die on said wafer to said loading section, and a frame supplying section for supplying said frame to said loading section; and
a pressure controlling section for controlling the internal pressure of said housing, wherein
a hollow portion is provided on at least a part of the facing surfaces of said die and die pad.

15. The die attach machine for a semiconductor device according to claim 14, wherein said housing further accommodates a sealing-material supplying section for supplying a sealing material to the facing surfaces of said die and die pad.

16. The die attach machine for a semiconductor device according to claim 15, wherein said sealing material is a glass material.

17. A method for die bonding a semiconductor device comprising the steps of:
mounting a die on a die pad provided with a hollow portion on at least a part of the surface facing to said die after reducing the pressure in a space where the mounting is performed; and
returning the reduced pressure of said space to the external pressure after said pressure-reducing step.

18. The method for die bonding a semiconductor device according to claim 17, prior to mounting the die on the die pad, further comprising the step of supplying a sealing-material to the facing surfaces of said die and die pad.

19. The method for die bonding a semiconductor device according to claim 18, wherein said sealing material is a glass material.
